(19) United States
(12) Patent Application Publication
(10) Pub. No.: US 2026/0264632 A1
(43) Pub. Date: Sep. 10, 2026

(54) GENERIC HIGH-VOLTAGE DC ELECTRICAL DISTRIBUTION PANEL

(71) Applicant: SAFRAN ELECTRICAL & POWER, Blagnac (FR)

(72) Inventors: Ludovic GUYOT, Blagnac (FR); Jérôme VALIRE, Blagnac (FR); Arnaud BADAULT, Blagnac (FR); Olivier DESHAYES, Blagnac (FR)

(73) Assignee: SAFRAN ELECTRICAL & POWER, Blagnac (FR)

(21) Appl. No.: 18/876,284

(22) PCT Filed: Jun. 12, 2023
(86) PCT No.: PCT/FR2023/050842

§ 371 Date: Dec. 18, 2024

(30) Foreign Application Priority Data
Jun. 21, 2022 (FR) FR2206112

(51) Int. Cl. B60R 16/033; B60L 50/60; H02B 1/06

(52) U.S. Cl. CPC B60R 16/033; B60L 50/60; H02B 1/06; B60L 2200/10

(57) ABSTRACT

A high-voltage DC electrical distribution panel provided to enable the installation of two electromechanical power contactors along either a series orientation or a parallel orientation. Locations for installing the chambers of fixed and movable contact terminals of the two contactors are disposed on a first of the major surfaces of the panel, while on the second major surface of the panel, locations are provided for installing the complementary assemblies of the two contactors, each complementary assembly including a motor intended to activate the contact terminals of the contactor in question. On the first of the surfaces, there is an installation location free of any contact terminal chamber and fixed contacts in this place are protected by a protection box with an incorporated shunt ensuring the continuity of the power connection. This device makes it possible to improve the insulation of the energized parts while ensuring a reduced bulk.

### DESCRIPTION

### Technical Field

This invention relates to the field of electrical power distribution, in particular in an aircraft, and more specifically to a generic high-voltage DC electrical power distribution panel.

### Prior Art

To distribute the power in an electrical power distribution network of an aircraft, one generally uses electrical distribution units equipped with electromechanical power contactors, Kn and Kp, intended to switch the power lines HV+ and HV⁻ between a source and a load. The power contactors, Kn and Kp, are used to switch the power on the one hand and to isolate the line on the other hand.

In general, in power distribution, the contactors Kn and Kp are associated with other components such as a precharging circuit. The precharging circuit is included on the power line HV+ with a contactor K1 and a power resistance R1. A current sensor moreover makes it possible to measure the current in the lines HV+ and HV− to control the contactors Kp, Kn and K1 and provide current protection for the distribution line. Control electronics activate the motors used to drive the contactors. The assembly constitutes a BPMU (Bus Power Management Unit) which can for example be used between a high-voltage battery and an electric motor in the case of all-electrical propulsion of a small aircraft. This BPMU is an example of a high-voltage cutoff device with a precharging resistor.

FIG. 1 shows the general block diagram of an example 10 of such a BPMU.

As can be seen in FIG. 1, the BPMU 10 intended to be contained in the power distribution unit includes a branch (precharging branch 12) parallel to the Kp/Kn main switching element 14 disposed between the electrical power source and the high and low voltage lines HV+ and HV− supplying the load. This pair Kp/Kn of electromechanical contactors provides galvanic isolation in the open state and a very low impedance (a hundred mV on nominal current) in the closed state. These electromechanical contactors are conventionally controlled from a control module 16 according to items of voltage and/or current information measured upstream and downstream of these contactors.

The elements of the precharging parallel branch 12, a contactor K1 and a limiting resistance R1 have an impedance defined to have a current 12 determined by the source voltage R1 corresponding to the precharging current of the load (typically of a few tens of amperes). The contactor K1 is also electromechanical to ensure galvanic isolation in the open state and also controlled by the control module 16.

The physical embodiment of the electrical power distribution units is based on a box and/or a panel. The specific arrangement of the different components of the BPMU depends on the application and the power distribution unit must therefore be made in a “bespoke” manner each time, according to the application. Only the basic components (switches, motors, resistances, etc.) are generic products and constitute the building blocks reused for the applications. In summary, distribution units are designed to adapt to the requirement based on mechanically incorporated discrete elements.

In his patent application FR 22 01421, the Applicant has made provision for a generic electrical distribution panel incorporating a large number of components while allowing adaptation to the operating requirement of distribution and precharging in a high-voltage DC network.

A top view of an example 40 of the generic power distribution panel of the patent application FR 22 01421 is shown in FIG. 2 and a bottom view is shown in FIG. 3.

In this generic power distribution panel, the contactors (for example the contactors Kp, Kn) are incorporated into the panel 40 which serves as a mechanical support for the assembly to make the solution compact and keep electrical and mechanical interfaces to a minimum. The motors, auxiliary contacts and beam of the movable part are on one side of the panel, while the contact chambers (fixed and movable) are on the other side of the panel.

More specifically, the panel 40 has two opposing major surfaces, 41 and 42. On the first surface 41 four contact chambers 45a, 46a, 45b and 46b are installed, housing the fixed and movable contact terminals of the contactors Kp and Kn. To prevent electrical arcs, these contact chambers 45a, 46a, 45b and 46b can, for example, be vacuum chambers or oil-filled chambers.

On the first surface 41 of the panel, power terminal blocks 31a, 31b, 34a, 34b are also installed to connect the panel to the power distribution circuit, to the source on the one hand and to the load or to the network on the other hand. Insulating screw protection caps 32a, 32b, 35a, 35b are provided to avoid the risk of short-circuits between the two polarities via an external object.

On the second surface 42 of the panel, complementary assemblies of the contactors 48a, 48b, and other components are installed. According to the example shown in FIG. 2, the other components include: a current probe 52, two resistances 54, 55, and a precharging contactor 56. Other components still (for example a fuse) may be present but are not shown.

The complementary assemblies of the contactors, 48a, 48b, include the motors, auxiliary contacts and beam of the movable part of the contactors Kp and Kn. The motors are indicated by 51a and 51b on the drawings. The motor 51a activates Kp.

This generic panel 40 can be used to implement the circuit shown in FIG. 1, along with other circuits. The generic panel in particular enables the arrangement of the complementary assemblies of the contactors along two orthogonal orientations allowing the motors to activate contact terminals of different sub-assemblies of the contact chambers and thus to make parallel or series configurations of the contactors. Attachment points 60 and screws 61 make it possible to attach the complementary assemblies of the contactors, 48a, 48b according to the desired configuration (in series or in parallel).

The components disposed on the second major surface 42 of the panel 40 are arranged in such a way as to leave a free space constituting an area of attachment of the complementary assemblies of the two contactors, the area of attachment being dimensioned to allow the arrangement of the complementary assemblies of the contactors along the two orthogonal orientations, a first orientation along which each of the motors of the complementary assemblies of contactors activates the terminals of a respective first sub-assembly of the contact terminal chambers, and a second orientation along which each of the motors of the complementary assemblies of contactors activates the terminals of a respective second sub-assembly of the contact terminal chambers, the contact chambers of the first and second sub-assemblies being aligned along respective orthogonal directions.

The center-to-center distances of the chambers of the contactors and the center-to-center distances of the complementary assemblies of the contactors are dimensioned to align the contacts of the two contactors with the corresponding motors of the complementary assemblies of the contactors along the first and the second orientation of the complementary assemblies of the contactors.

Thus, the modular generic panel having incorporated contactors on a power panel and allowing two configurations of arrangement simplifies adaptation to the operating requirement of distribution and precharging in a high-voltage DC network. The high level of integration of the components on the power panel makes it possible to optimize the mass and volume of the function. The modularity of the solution also makes it possible to meet different needs owing to the proposed configurations, which can make it generic.

However, the generic panel 40 also enables the production of circuits which need only two contactors, i.e. circuits that omit either Kp or Kn, in which case it is possible to dispense, for each omitted contactor, with two contact chambers at the locations provided on the surface 41 of the panel. FIG. 4 shows the area 47a of the generic panel in which the fixed contacts 371, 372 are then located when a contact chamber is not installed in one of the locations provided on the surface 41 of the panel: in the example shown in FIG. 4, the contact chamber 45a has been omitted from the device.

As can be seen in FIG. 4, when there is no contact chamber installed at one of the locations provided on the surface 41 of the panel, the fixed contacts are then non-insulated and the power connection is interrupted. Until now, to protect the fixed contacts in such a scenario, provision has been made for installing an insulating cover 50 on the surface 41 of the panel, this insulating cover 50 covering the area 35a where the fixed contacts are located. To provide the power connection, a power bar 30 is added to the assembly, along with associated attachment elements 39 (power stud, etc.) Such a configuration is shown in FIG. 5 (which shows the scenario in which the contact chamber 45b has been omitted from the device).

This prior approach therefore involves adding electrical connection parts (terminals, bar, nuts and bolts) and an insulating cover to cover the fixed contacts, which increases the bulk of the device. Such an arrangement is shown in FIG. 5.

Moreover, the power bar shown in FIG. 5 includes mechanical assemblies to make the electrical connections in the event of a configuration with two contactors being used. These connections cannot be completely insulated and therefore have bare and exposed energized metallic parts. This can be dangerous for maintenance operators or be the source of electrical defects in the presence of a metallic foreign body in this area.

This invention has the aim of palliating the drawbacks mentioned above.

### SUMMARY OF THE INVENTION

This invention therefore has the main aim of making provision for a generic electrical power distribution panel which is modular, with incorporated contactors on the power panel, configured to allow adaptation to the operating requirement of distribution and precharging in a high-voltage DC network including to allow an adaptation involving the absence of a movable contact at one of the installation locations provided on the panel.

These aims are achieved by a high-voltage DC electrical distribution panel, characterized in that:
on a first of the major surfaces of the panel locations are provided for installing the chambers of fixed and movable contact terminals of two electromechanical contactors, one pair of fixed contacts being provided at each contact chamber installation location, while on the second major surface of the panel, locations are disposed for installing the complementary assemblies of the two contactors, these assemblies each including a respective motor intended to activate the contact terminals of one of the respective contactors, a protection component is installed at at least one of the contact chamber installation locations, instead and in place of the movable contact, said protection component including: an insulating cover defining with the surface of the panel an enclosed space including an electrical connection shunt arranged to link the pair of fixed contacts to one another.

The panel according to the configuration described above makes it possible to have the best possible integration, and makes it possible to link the fixed contacts in a small bulk.

In a preferred embodiment, the protection component of the aforementioned high-voltage electrical distribution panel includes a pressurized spring arranged to push the connection shunt against the fixed contacts. In this way, the continuity of the current path is ensured with increased reliability.

In a preferred embodiment, the aforementioned high-voltage electrical distribution panel includes a precharging function. This configuration makes it possible to obtain a large reduction in terms of mass and volume by comparison with the devices for which provision was previously made and which include a precharging function.

The invention also relates to a high-voltage DC electrical distribution unit equipped with the aforementioned high-voltage distribution panel. In a preferred embodiment, the aforementioned high-voltage electrical distribution panel is installed between a storage unit and a high-voltage DC (HVDC) bus of an aircraft. Advantageously, the storage unit can be a battery or a supercapacitor.

The invention also relates to an electrical power distribution network of an aircraft including an electrical power distribution unit as mentioned above.

### BRIEF DESCRIPTION OF THE FIGURES

Other features and advantages of this invention will become apparent from the description given below, with reference to the appended drawings which illustrate an exemplary embodiment thereof without any limitation and in which:

FIG. 1 shows the general block diagram of an example of an electrical distribution unit equipped with electromechanical power contactors of the prior art.

FIG. 2 shows a top view of a generic high-voltage DC distribution panel, with complementary assemblies of power contactors arranged along a first orientation,

FIG. 3 shows a bottom view of the high-voltage distribution panel of FIG. 2,

FIG. 4 shows an uncovered fixed contactor area of the lower surface of the high-voltage DC distribution panel of FIG. 2,

FIG. 5 shows a power bar used in the prior art to protect the fixed contactor area,

FIG. 6 is a diagram showing a panel equipped, on one side, with a power bar according to FIG. 5 and, on the other side, a protection component according to an embodiment of the invention, and

FIG. 7 is a section view of an example of the protection component shown in FIG. 6.

### DESCRIPTION OF THE EMBODIMENTS

The invention relies on the configuration of a high-voltage electrical distribution panel in such a way as to incorporate a large number of components, while allowing adaptation to the operating requirement of distribution and precharging in a high-voltage DC network, including an adaptation involving the absence of a contact terminal chamber at one of the locations provided on the panel.

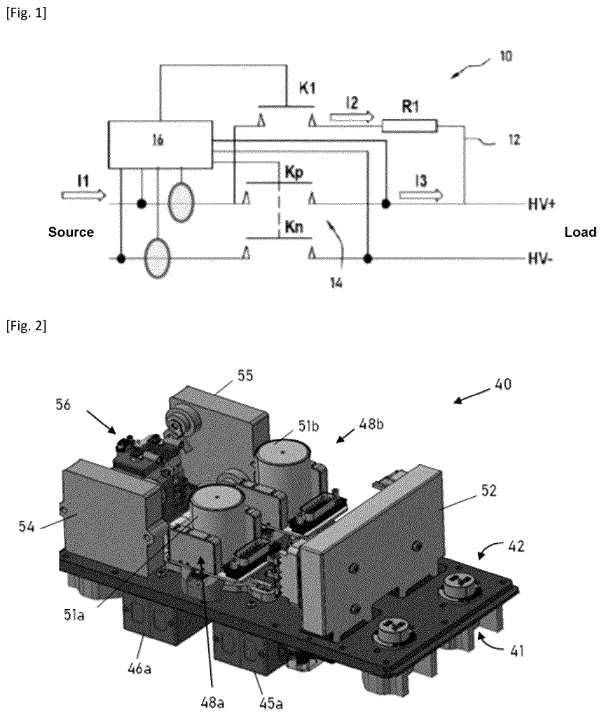

The panel can be used, in particular, for the production of a light BPMU, the general block diagram of which is equivalent to that shown in FIG. 1. Such a light BPMU can, for example, be used between a high-voltage storage means (for example, a battery or a supercapacitor) and an electric motor in the case of an all-electrical propulsion of a small aircraft.

As described in the patent application FR 22 01421, the panel is designed such that the contactors Kp and Kn can be installed along two orientations on the same panel owing to a carefully chosen geometry and center-to-center distances. For this purpose, on one of the major surfaces of the panel, locations are provided for installing four contact chambers housing the fixed and movable contact terminals of the contactors Kp and Kn. However, depending on the application, one may only need to use one of the two contactors Kn and Kp.

According to an example, the panel houses the high-voltage DC contactor K1 for a precharging line on the power line HV+, the power resistance R1 for current limiting in the precharging line on the line HV+, a current sensor on the lines HV+ and HV−, a high-voltage DC contactor Kp on the line HV+ or a high-voltage DC contactor Kn on the line HV−, and control electronics for the contactors Kp/Kn and K1 and for the management of the current measurements.

According to this example, as the device houses only one of the two contactors Kn and Kp, there is no need to install all four chambers of the fixed and movable contact terminals. More precisely, it is possible to dispense with one movable contact. On the panel there is therefore one location for installing a contact terminal chamber which is free of any contact chamber. As a pair of fixed contacts is disposed at this location, according to an embodiment of the invention, a new component is provided to protect the fixed contacts and provide the power connection. This is a component which is equivalent to a sub-assembly that protects the fixed contacts, and which has an incorporated electrical shunt (a conductive link, for example a metallic link) instead and in place of the movable contact positioned to be seated on the fixed contacts.

This solution makes it possible to simultaneously offer configurability of the panel while securing the electrical connections since the link thus made by the shunt is covered and fully insulated.

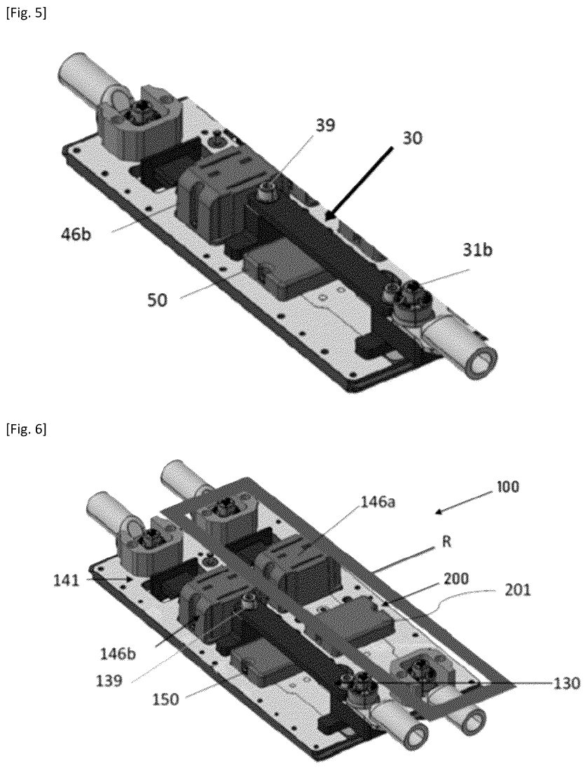

FIG. 6 shows a panel 100 which has an incorporated protection component 200 according to an embodiment of the invention, along with a power bar 30 according to the approach illustrated by FIG. 5. A rectangle R in FIG. 6 indicates the region corresponding to the configuration according to the embodiment of the invention.

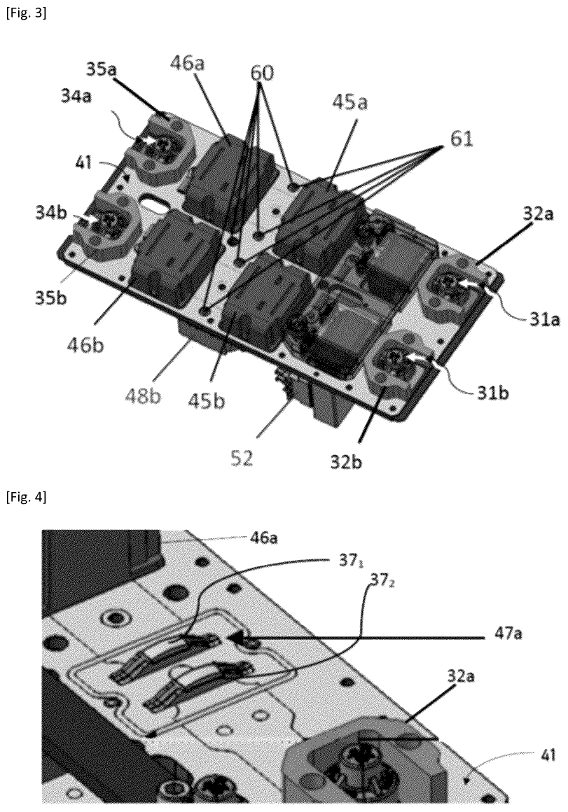

To simplify the description, similar elements to those shown in FIGS. 2 to 5 are denoted in FIG. 6 by equivalent reference numbers preceded by the FIG. 1 (thus, for example, the contact chamber 146a of FIG. 6 is equivalent to the contact chamber 46a of FIG. 3). The description of the elements in question is therefore omitted or shortened below.

In FIG. 6, the two configurations are shown side-by-side in order to allow a visual comparison between these configurations and thus a better appreciation of the advantages resulting from the invention, particularly in terms of the reduced volume occupied by the solution according to the invention. However, those skilled in the art will understand that, in practice, it is preferable to use only the solution provided by the invention, i.e. protection components 200 at all the installation locations of contact terminal chambers which are free of any contact/movable contact chamber.

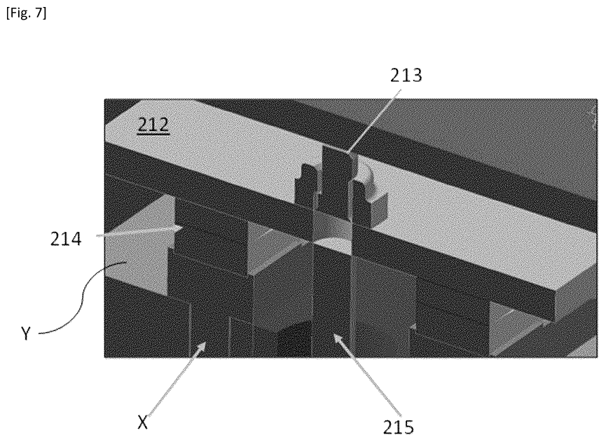

The protection component 200 is an element which includes a conductive link (for example a narrow metallic panel 212 according to the example of FIG. 7) arranged to serve as a power connection shunt, i.e. to provide the power connection by linking the fixed contacts which are found at the contact chamber installation location where this protection component is being installed 200. The protection component 200 also includes an insulating cover 201.

FIG. 6 shows the difference in integration and in volume between the current solution and the embodiment of the invention in the rectangle R. The installation of the elements on the left corresponds to the prior art with a power bar which is found bare and exposed. The installation described on the right-hand part shows the embodiment for which provision is made to optimize the bulk and dispense with the energized bar.

The embodiment for which provision is made makes it possible to dispense with the power stud 139 and the power bar 130 not covered with insulant, as well as the insulating cover 150.

The panel 100 includes a plate 110 which serves as a “mechanical” structure to support the assembly. According to an embodiment of the invention, the plate 110 is made of epoxy, for example of FR4 or FR5 type.

The panel 100 houses the following components:
power terminal blocks 31a, 31b, 34a, 134b to connect the panel to the power distribution circuit, to the source on the one hand, and to the load or to the network on the other hand
insulating screw protection caps 32a, 32b, 35a, 35b to avoid the risk of short-circuits between the two polarities via an external object
the contactor chambers 46a, 46b, 46A, 46b, and
the protection component 200 which corresponds to a sub-assembly with an incorporated shunt.

As can be seen in FIG. 6, the use of the protection component 200 makes it possible to reduce the number of parts and to have better integration, which procures savings in mass and makes the modularity as simple as possible. A standardization suited to the different configurations of the generic high-voltage DC (HVDC) electrical power distribution device of the power contact shunt sub-assembly 200 is then possible.

FIG. 7 shows a section view of an exemplary embodiment of the protection component 200 of FIG. 6. According to this example, the protection component 200 is composed of the following elements:
a movable connection bar 212: power transfer between the two contact pads.
a retaining screw 213: attachment between the movable bar and the translation shaft
a contact pad 214: transfer of the power the HV power bars and the movable contact, and
a shaft 215, it allows contact to be made by translation and maintaining of the contact pressure between the pads and the power bars in the active state. In the idle state it guarantees the separation of the contacts.

As long as it includes the power connection shunt arranged to link the fixed contacts, and the isolation provided by a cover or other means, the protection component 200 can be modified with respect to the example shown in FIG. 7, for example according to the needs of the application or the desires of the designer. For example, a spring can be added to emphasize the connection.

According to other embodiments of the invention, a panel as described above is incorporated into an electrical power distribution unit, for example an electrical distribution unit installed between a storage unit and a high-voltage DC (HVDC) bus of an aircraft.

According to other embodiments of the invention, an electrical power distribution network of an aircraft includes a high-voltage DC electrical distribution unit with an incorporated panel as described above.

The invention has a particular application in the aeronautical industry and the automotive industry, for example in relation to a power generation channel, a HVDC battery, a fuel cell, primary distribution, secondary distribution, electrical propulsion, hybrid propulsion, etc.

The devices provided by the invention allow a reduction in the number of parts and better integration, in order to make savings in mass and make the modularity as simple as possible. A standardization adapted to the different configurations of the generic high-voltage DC (HVDC) electrical power distribution panel of the power contact shunt sub-assembly is then possible.

1. A high-voltage DC electrical distribution panel, having two opposing major surfaces, wherein:
on a first of the major surfaces of the panel locations are provided for installing the chambers of fixed and movable contact terminals of two electromechanical contactors, one pair of fixed contacts being provided at each contact chamber installation location, while on the second major surface of the panel, locations are disposed for installing the complementary assemblies of the two contactors, these assemblies each including a respective motor intended to activate the contact terminals of one of the respective contactors,
a protection component is installed at least one of the contact chamber installation locations, instead and in place of the movable contact, said protection component including: an insulating cover defining with the surface of the panel an enclosed space including an electrical connection shunt arranged to link the pair of fixed contacts to one another.

2. The high-voltage DC electrical distribution panel as claimed in claim 1, wherein the protection component includes a pressurized spring arranged to push the connection shunt against the fixed contacts.

3. The high-voltage DC electrical distribution panel as claimed in claim 1, including a pre-charging function.

4. A high-voltage DC electrical distribution unit installed between a storage unit and a high-voltage DC bus of an aircraft, said distribution unit including a panel as claimed in claim 1.

5. The electrical distribution unit as claimed in claim 4, wherein the storage unit is a battery or a super capacitor.

6. An electrical power distribution network of an aircraft including a high-voltage DC electrical distribution unit as claimed in claim 4.
